(19) United States
(12) Patent Application Publication
(10) Pub. No.: US 2026/0190750 A1
(43) Pub. Date: Jul. 2, 2026

(54) DISPLAY DEVICE

(71) Applicant: LG Display Co., Ltd., Seoul (KR)

(72) Inventors: Minwoo NAM, Paju-si (KR); Kihyung LEE, Paju-si (KR)

(73) Assignee: LG Display Co., Ltd., Seoul (KR)

(21) Appl. No.: 19/343,552

(22) Filed: Sep. 29, 2025

(30) Foreign Application Priority Data
Dec. 27, 2024 (KR) 10-2024-0198927

(51) Int. Cl. H10K 59/00; H10K 59/131; H10K 59/80

(52) U.S. Cl. CPC H10K 59/771; H10K 59/131; H10K 59/80521

(57) ABSTRACT

The present disclosure provides a display device including a substrate having a display area, a light emitting element disposed within the display area, and an auxiliary line also positioned in the display area. The light emitting element includes a first cathode electrode on the substrate, a first intermediate layer on the first cathode electrode, an anode electrode on the first intermediate layer, a second intermediate layer on the anode electrode, and a second cathode electrode on the second intermediate layer. The auxiliary line is electrically connected to both the first cathode electrode and the second cathode electrode within the display area. This structure enables the display device to be driven at a low voltage, enhancing power efficiency while maintaining luminance performance.

### CROSS REFERENCE TO RELATED APPLICATION

This application claims priority from Korean Patent Application No. 10-2024-0198927, filed on Dec. 27, 2024 in the Korean Intellectual Property Office, which is hereby incorporated by reference for all purposes as if fully set forth herein.

### BACKGROUND

### Technical Field

The present disclosure relates to electronic devices, and more specifically, to display devices.

### Description of the Related Art

In today's information society, display devices for presenting images or visual information to users are increasingly important. The needs for such display devices have caused display technology to be rapidly developed, and various types or usages of display devices have been developed. In addition, as display devices are becoming thinner and lighter, usages of the display devices are increasingly expanding, and displays are widely being applied in various fields of devices, apparatuses, and systems.

Display devices tend to add various functions including functions interoperated or associated with other devices, apparatuses, and systems, as well as stand-alone functions, even when an area occupied by a display area for displaying images is increased.

As display devices with high efficiency and luminance are increasingly desired, work has been progressing on display devices capable of being driven at low voltage and reducing a degree of heat generation.

In addition, as a so-called bezel-less or bezel-free design, which makes a display screen appear to fill a whole viewing surface of a display device, is increasingly becoming popular, recently work has been progressing on reducing an area of a non-display area outside of the display area.

### BRIEF SUMMARY

Various embodiments of the disclosed display device include a structure that uses parallel type light emitting elements, in which two emission stacks are symmetrically positioned on either side of a shared anode and connected in parallel through separate cathodes. This configuration allows operation at reduced voltage, increases light emitting efficiency, and decreases heat generation, all without requiring changes to the materials used. In addition, auxiliary lines and connection patterns are incorporated directly within the active display area rather than in the bezel region, which supports narrower bezels, decreases the spacing between subpixels to achieve higher resolution, and enhances uniformity of luminance across the display.

This structure is further supported by multi layer thin film transistor circuits, gate drivers integrated within the panel, and electrode configurations that are adapted for top emission, bottom emission, or dual emission. The inclusion of light absorbing black banks and layered capacitors improves optical performance and electrical reliability. The use of transparent and reflective electrode materials, advanced encapsulation techniques, and a variety of subpixel circuit configurations such as two transistor one capacitor and six transistor two capacitor designs contribute to improved durability, efficient manufacturing, and enhanced display performance. These features make the disclosed technology suitable for application in a wide range of electronic devices, including smartphones, foldable displays, and wearable electronics.

For example, one or more aspects of the present disclosure may provide a display device that includes a structure where parallel-type light emitting elements are disposed, and is capable of being driven at low voltage and improving light emitting efficiency.

One or more aspects of the present disclosure may provide a display device that includes a structure where parallel-type light emitting elements are disposed, and is capable of reducing heat generation of the light emitting elements.

One or more aspects of the present disclosure may provide a display device that includes a structure where a cathode electrode, an auxiliary line, and a connection pattern are disposed in a display area, and is capable of improving an unevenness in luminance between areas in a display area.

One or more aspects of the present disclosure may provide a display device that includes a structure where a cathode electrode, an auxiliary line, and a connection pattern are disposed in a display area, and is capable of reducing a distance between subpixels (e.g., a width of a non-light emitting area) and thereby achieving high resolution.

One or more aspects of the present disclosure may provide a display device that includes a structure where a cathode electrode, an auxiliary line, and a connection pattern are disposed in a display area, and is capable of reducing a width of a bezel area and thereby realizing a narrow bezel.

One or more aspects of the present disclosure may provide a display device that includes a structure where parallel-type light emitting elements are disposed, and is capable of enabling process optimization without changing materials.

One or more aspects of the present disclosure may provide a display device capable of reducing a distance between subpixels, and achieving high resolution and low power driving.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can be provided that includes a substrate including a display area, at least one light emitting element disposed in the display area, and an auxiliary line disposed in the display area. In one or more aspects, the light emitting element may include a first cathode electrode on the substrate, a first intermediate layer on the first cathode electrode, an anode electrode on the first intermediate layer, a second intermediate layer on the anode electrode, and a second cathode electrode on the second intermediate layer. In one or more aspects, the auxiliary line may be electrically connected to the first cathode electrode and the second cathode electrode in the display area.

According to one or more aspects of the present disclosure, a display device may be provided that is capable of being driven at low voltage and improving light emitting efficiency by including a structure where parallel-type light emitting elements are disposed.

According to one or more aspects of the present disclosure, a display device may be provided that is capable of reducing heat generation of light emitting elements by including a structure where parallel-type light emitting elements are disposed.

According to one or more aspects of the present disclosure, a display device may be provided that is capable of improving an unevenness in luminance between areas in a display area by including a structure where a cathode electrode, an auxiliary line, and a connection pattern are disposed in a display area.

According to one or more aspects of the present disclosure, a display device may be provided that is capable of reducing a distance between subpixels (e.g., a width of a non-light emitting area) and thereby achieving high resolution by including a structure where a cathode electrode, an auxiliary line, and a connection pattern are disposed in a display area.

According to one or more aspects of the present disclosure, a display device may be provided that is capable of reducing a width of a bezel area and thereby realizing a narrow bezel by including a structure where a cathode electrode, an auxiliary line, and a connection pattern are disposed in a display area.

According to one or more aspects of the present disclosure, a display device may be provided that is capable of enabling process optimization without changing materials by including a structure where parallel-type light emitting elements are disposed.

According to one or more aspects of the present disclosure, a display device may be provided that is capable of reducing a distance between subpixels, and achieving high resolution and low power driving.

Effects or advantages from aspects, examples, and embodiments described herein are not limited thereto, and additional effects or advantages will become apparent to those skilled in the art from the following description.

### BRIEF DESCRIPTION OF THE SEVERAL VIEWS OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example system configuration of a display device according to aspects of the present disclosure;

FIG. 2 illustrates an example light emitting element having a tandem stack structure in the display device according to aspects of the present disclosure;

FIG. 3 illustrates an example light emitting element in the display device according to aspects of the present disclosure;

FIG. 4 is an example plan view of a display panel according to aspects of the present disclosure;

FIG. 5 is a cross-sectional view taken along line A-B of FIG. 4;

FIG. 6 is an example enlarged cross-sectional view of area X in FIG. 5;

FIG. 7 is an example enlarged cross-sectional view of area X in FIG. 5;

FIG. 8 is an example enlarged cross-sectional view of area X in FIG. 5; and

FIGS. 9 to 14 illustrate an example process for manufacturing a light emitting element according to aspects of the present disclosure.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts,” “overlaps with,” or the like a second element, it should be interpreted that, not only can the first element “be directly connected or coupled to,” “directly contact,” or “directly overlap with” the second element, but a third element can also be “interposed” between the first and second elements, or the first and second elements can “be connected or coupled to,” “contact,” “overlap with,” or the like each other via a fourth element. Here, the second element may be included in at least one of two or more elements that “are connected or coupled to,” “contact,” “overlap with,” or the like each other.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes, etc., are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can.”

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

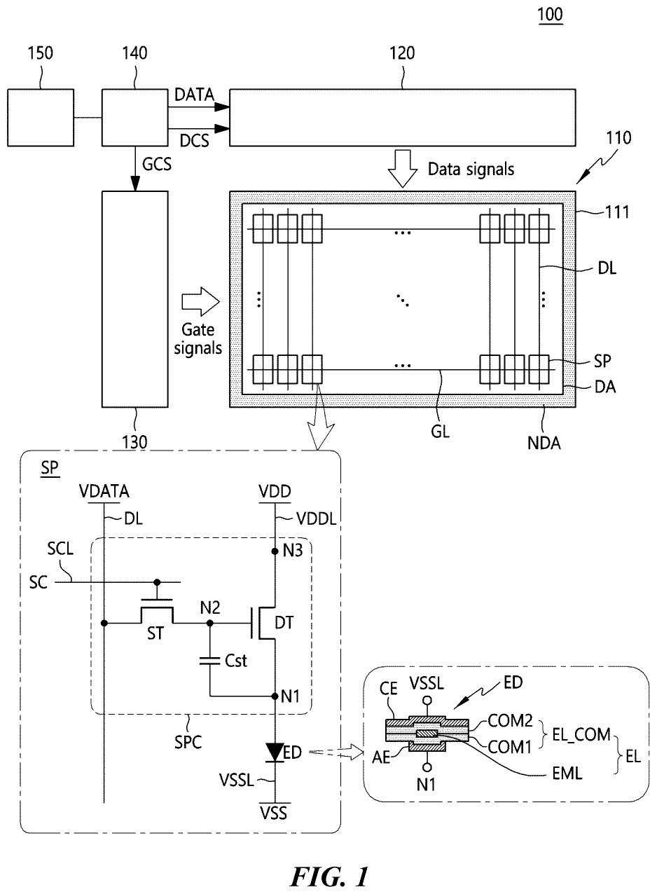

FIG. 1 illustrates an example system configuration of a display device 100 according to aspects of the present disclosure.

Referring to FIG. 1, in one or more example embodiments, the display device 100 may include a display panel 110 and at least one display driving circuit, as elements for display images. The at least one display driving circuit may be a circuit for driving the display panel 110, and include a data driving circuit 120, a gate driving circuit 130, a controller 140, and other circuit components.

The display panel 110 may include a substrate 111 and a plurality of subpixels SP disposed on the substrate 111.

The substrate 111 may include a display area DA allowing an image to be displayed and a non-display area NDA around an outer edge of the display area DA.

The display area DA may also be referred to as an active area, and a plurality of subpixels SP for displaying images may be disposed in the display area DA. The non-display area NDA may also be referred to as a non-active area and include a pad area PA.

In one or more aspects, the display panel 110 may be configured to have a very small non-display area NDA. The non-display area NDA may be also referred to as a “bezel” or an “bezel area.” For example, the non-display area NDA may include a first non-display area located outside of the display area DA in a first direction, a second non-display area located outside of the display area DA in a second direction, a third non-display area located outside of the display area DA in a direction opposite to the first direction, and a fourth non-display area located outside of the display area DA in a direction opposite to the second direction.

The first non-display area among the first to fourth non-display areas may include a pad area to which one or more driving circuits are connected or bonded. Among the first to fourth non-display areas, the second to fourth non-display areas may have a very small size compared to the first non-display area.

In one or more aspects, a boundary area may be defined between the display area DA and the non-display area NDA. For example, the boundary area may be bent at a certain angle to the display area DA, and thereby, the non-display area NDA may be located under the display area DA. In this implementation, when a user views the display device 100 in front thereof, all or most of the non-display area NDA may be invisible to the user. For example, the first non-display area may include a bending area. As the bending area is bent, the first non-display area may be invisible in front of the display device 100.

Several types of signal lines for driving a plurality of subpixels SP may be disposed on the substrate 111 of the display panel 110.

In one or more aspects, the display device 100 herein may be a liquid crystal display device, or the like, or a self-emissive display device in which light is emitted from the display panel 110 itself. In an example where the display device 100 is the self-emissive display device, each of the plurality of subpixels SP may include a light emitting element.

For example, the display device 100 according to aspects of the present disclosure may be an organic light emitting display device in which light emitting elements are implemented using organic light emitting diodes (OLED). In another example, the display device 100 according to aspects of the present disclosure may be an inorganic light emitting display device in which light emitting elements are implemented using inorganic material-based light emitting diodes. In further another example, the display device 100 according to aspects of the present disclosure may be a quantum dot display device in which light emitting elements are implemented using quantum dots, which are self-emission semiconductor crystals.

The structure of each or at least one of a plurality of subpixels SP included in the display device 100 may depend on types of the display device 100. For example, when the display device 100 is a self-emissive display device including self-emissive subpixels SP, each subpixel SP may include a self-emissive light emitting element, one or more transistors, and one or more capacitors.

Referring to FIG. 1, each or at least one of the plurality of subpixels SP disposed in the display panel 110 may include a light emitting element ED and a subpixel circuit SPC configured to drive the light emitting element ED.

Referring to FIG. 1, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT configured to drive the light emitting element ED and a scan transistor ST configured to be turned on or off by a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a voltage at a constant level during a display frame or a period of the display frame.

To drive at least one subpixel SP, at least one data signal VDATA, which is an image signal, and at least one scan signal SC, which is a gate signal, may be applied to the at least one subpixel SP. Further, to drive at least one subpixel SP, at least one common voltage including a first common voltage VDD and a second common voltage VSS may be applied to the at least one subpixel SP.

The light emitting element ED may include an anode electrode AE, an intermediate layer EL, and a cathode electrode CE. The intermediate layer EL may be disposed between the anode electrode AE and the cathode electrode CE.

For example, the anode electrode AE may be an electrode disposed for each subpixel SP, and the cathode electrode CE may be an electrode commonly disposed in all or some of a plurality of subpixels SP.

In an example where the light emitting element ED is an organic light emitting diode, the intermediate layer EL may include an emission layer EML, a hole functional layer COM1 between the anode electrode AE and the emission layer EML, and an electron functional layer COM2 between the emission layer EML and the cathode electrode CE. A layer including the hole functional layer COM1 and the electron functional layer COM2 may be referred to as a functional layer EL_COM.

The emission layer EML, the hole functional layer COM1 and the electron functional layer COM2 may be disposed for each subpixel SP.

The emission layer EML, the hole functional layer COM1 and the electron functional layer COM2 may be disposed for each light emitting area.

For example, the hole functional layer COM1 may include at least one of a hole injection layer HIL and a hole transfer layer HTL. The electron functional layer COM2 may include at least one of an electron transport layer ETL and an electron injection layer EIL.

The hole injection layer HIL can inject holes from the anode electrode AE into the hole transport layer HTL, and the hole transport layer HTL can transport holes to the emission layer EML. The electron injection layer EIL can inject electrons from the cathode electrode CE into the electron transport layer ETL, and the electron transport layer ETL can transport electrons to the emission layer EML.

In one or more aspects, light emitting elements ED may be disposed in a bottom emission (BE) structure, a top emission (TE) structure, or a dual emission (DE) structure. For example, in the bottom emission (BE) structure, light emitting elements ED may be configured to emit light in a direction toward a substrate 111, i.e., in a downward direction. For example, in the top emission (TE) structure, light emitting elements ED may be configured to emit light in a direction opposite to the substrate 111, i.e., in an upward direction. For example, in the dual emission (DE) structure, light emitting elements ED may be configured to emit light in both the direction toward the substrate 111 and the direction opposite to the substrate 111, in downward and upward directions.

In one or more aspects, the cathode electrode CE may be electrically connected to a second common voltage line VSSL. A second common voltage VSS may be applied to the cathode electrode CE through the second common voltage line VSSL. The anode electrode AE may be electrically connected directly or indirectly (via another transistor) to a first node N1 of a corresponding driving transistor DT of each subpixel SP.

Herein, a first common voltage VDD may also be referred to as a “high voltage” or a “driving voltage,” and a first common voltage line VDDL may also be referred to as a “high voltage line,” or a “driving voltage line.” Herein, the second common voltage VSS may also be referred to as a “low voltage” or a “base voltage,” and the second common voltage line VSSL may also be referred to as a “low voltage line” or a “base voltage line.

Each light emitting element ED may be configured by overlapping of an anode electrode AE, an emission layer EML in an intermediate layer EL, and a cathode electrode CE. A respective light emitting area may be formed by each light emitting element ED. For example, a respective light emitting area of each light emitting element ED may include an area where an anode electrode AE, an emission layer EML in an intermediate layer EL, and a cathode electrode CE overlap with each other

In one or more aspects, the light emitting element ED may be an organic light emitting diode (OLED), an inorganic light emitting diode (LED), a quantum dot light emitting element, or the like. In the example where each light emitting element ED is an organic light emitting diode (OLED), the intermediate layer EL of a corresponding light emitting element ED may be a layer including an organic material.

The driving transistor DT may be a transistor configured to supply a driving current to the light emitting element ED. The driving transistor DT may be connected between a first common voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common voltage VDD delivered through the first common voltage line VDDL may be applied to the third node N3.

In the driving transistor DT, the second node N2 may be a gate node, the first node N1 may be a source node or a drain node, and the third node N3 may be the drain node or the source node. Hereinafter, for merely convenience of explanation, discussions may be provided based on examples where the second node N2 is a gate node, the first node N1 is a source node or a drain node, and the third node N3 id the drain node or the source node. However, aspects of the present disclosure are not limited thereto.

The scan transistor ST included in the subpixel circuit SPC illustrated in FIG. 1 may be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node N1 and the second node N2 of the driving transistor DT.

Each of the driving transistor DT and the scan transistor ST may be an n-type transistor or a p-type transistor.

The display panel 110 may have the top emission structure or the bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

As shown in FIG. 1, the subpixel circuit SPC may include two transistors (2T: DT and ST) and one capacitor (1C: Cst) (which may be referred to as a “2T1C structure”), and in some implementations, may further include one or more transistors, or further include one or more capacitors.

For example, the subpixel circuit SPC may have an 8T1C structure including 8 transistors and 1 capacitor. In another example, the subpixel circuit SPC may have an 6T2C structure including 6 transistors and 2 capacitor. In another example, the subpixel circuit SPC may have an 7T1C structure including 7 transistors and 1 capacitor. However, aspects of the present disclosure are not limited to such specific structures.

The types and number of signals supplied to a subpixel SP, and/or the types and number of lines connected to the subpixel SP may vary depending on a structure of a corresponding subpixel circuit SPC. Further, the types and number of common driving voltages supplied to a subpixel SP may vary depending on a structure of a corresponding subpixel circuit SPC.

The several types of signal lines may include, for example, a plurality of data lines DL for carrying data signals (which may be referred to as data voltages or image signals), a plurality of gate lines GL for carrying gate signals (which may be referred to as scan signals), and the like.

In one or more aspects, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column direction, and the second direction may be the row direction. In another example, the first direction may be the row direction, and the second direction may be the column direction. Hereinafter, for merely convenience of explanation, discussions are provided based on examples where the first direction is the column direction and the second direction is the row direction. Hereinafter, for convenience of explanation, discussions may be provided based on examples where each of a plurality of data lines DL is disposed in the column direction, and each of a plurality of gate lines GL is disposed in the row direction, but aspects of the present disclosure are limited thereto.

The data driving circuit 120 may be a circuit for driving a plurality of data lines DL and can output data signals to the plurality of data lines DL.

The data driving circuit 120 can receive image data DATA in a digital form from the controller 140, and convert the received image data DATA into data signals in an analog form, and output the converted data signals to the plurality of data lines DL.

In some aspects, the data driving circuit 120 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

In one or more aspects, the data driving circuit 120 may be disposed in, and/or electrically connected to, but not limited to, only one side or edge (e.g., an upper portion or a lower portion) of the display panel 110. In one or more aspects, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to an area outward from the display area DA of the display panel 110, or be disposed in the display area DA of the display panel 110.

The gate driving circuit 130 may be a circuit configured to drive a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more aspects, the gate driving circuit 130 included in the display device 100 may be embedded into the display panel 110 by a gate-in-panel (GIP) technique. In an example where the gate driving circuit 130 is implemented by the gate-in-panel (GIP) technique, the gate driving circuit 130 may be disposed on the substrate 111 of the display panel 110 during the manufacturing process of the display panel 110 or display device 100.

In one or more aspects, the gate driving circuit 130 may be disposed in the non-display area NDA of the display panel 110.

In one or more aspects, the gate driving circuit 130 may be disposed in the display area DA of the display panel 110. In this implementation, for example, the gate driving circuit 130 may be disposed in, and/or electrically connected to, but not limited to, a first area (e.g., a left area or a right area) of the display area DA of the display panel 110. In another example, the gate driving circuit 130 may be disposed in, and/or electrically connected to, but not limited to, a first area (e.g., a left area or a right area) and a second area (e.g., the right area or the left area) of the display area DA of the display panel 110.

Herein, the gate driving circuit 130 embedded in the display panel 110 by the gate-in-panel (GIP) technique may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied or a location of the touch (or touch coordinates) based on the touch sensing data.

The display device 100 may further include a power supply circuit configured to supply various types of power to the display driving circuit and/or the touch sensing circuit.

In some aspects, the display device 100 may be a mobile terminal such as a smart phone, a tablet, or the like, or a monitor, a television (TV), or the like. Such devices may be configured in various types, sizes, and shapes. For example, the display device 100 according to aspects of the present disclosure may be applied to mobile devices, video phones, smart watches, watch phones, wearable devices, foldable devices, rollable devices, bendable devices, flexible devices, stretchable devices, curved devices, sliding devices, variable devices, electronic notebooks, e-books, portable multimedia players (PMP), personal digital assistants (PDA), MP3 players, mobile medical devices, desktop PCs, laptop PCs, netbook computers, workstations, navigation devices, car navigation devices, vehicle display devices, vehicle apparatuses, theater apparatuses, theater display devices, televisions, wallpaper devices, signage devices, game devices, notebook computers, monitors, cameras, camcorders, and home appliances, and the like.

In one or more aspects, the display device 100 may further include an electronic device such as a camera (e.g., an image sensor), a sensor capable of detecting an object, ambient light, and the like. For example, the sensor may be a sensor capable of detecting an object or a human body by receiving light such as infrared light, ultrasonic light, ultraviolet light or the like.

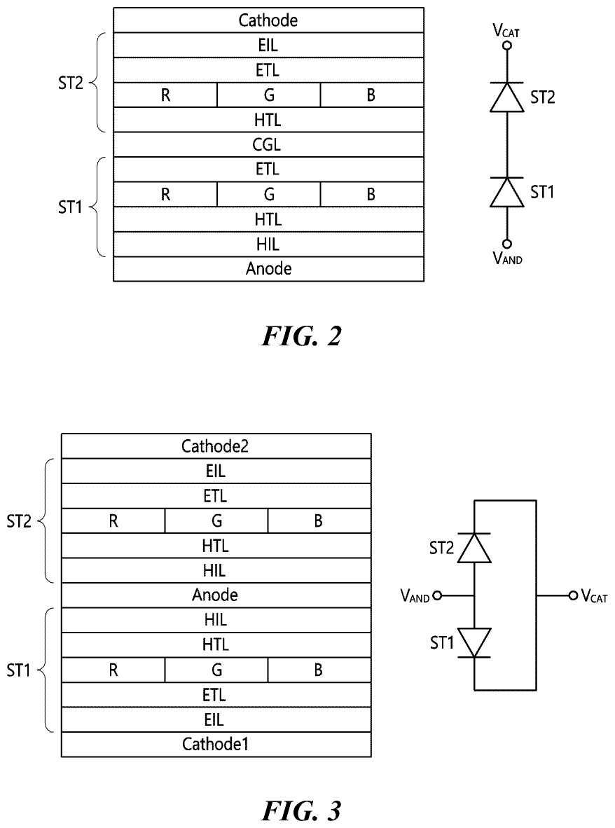

FIG. 2 illustrates an example light emitting element having a tandem stack structure in the display device 100 according to aspects of the present disclosure. Hereinafter, discussions for the configuration of FIG. 2 are provided, and discussions for features equal, substantially equal, or similar to the features described with reference to FIG. 1 may be omitted or briefly described for conciseness.

A stack-up structure of a light emitting element in which an anode electrode AE, a hole injection layer HIL, a hole transport layer HTL, an emission layer EML, an electron transport layer ETL, an electron injection layer EIL, and a cathode electrode CE are stacked in this order may be called a single stack structure. A light emitting element with the single stack structure may have disadvantages of producing a limited level of luminance due to low efficiency, and having a short lifetime.

Referring to FIG. 2, a light emitting element may have a tandem structure in which a first emission stack ST1 (also referred to as ‘a first stack ST1’) and a second emission stack ST2 (also referred to as ‘a second stack ST2’) are disposed between an anode electrode AE and a cathode electrode CE.

For example, the first stack ST1 may include a hole injection layer HIL, a hole transport layer HTL, an emission layer EML, and an electron transport layer ETL, and the second stack ST1 may include a hole transport layer HTL, an emission layer EML, an electron transport layer ETL, and an electron injection layer EIL. A charge generation layer CGL may be disposed between the first stack ST1 and the second stack ST2, and the first stack ST1 and the second stack ST2 may be connected in series.

The light emitting element with the tandem structure may have advantages of having an improved lifetime and producing high brightness, but have disadvantages of causing increased resistance due to the multilayer structure and being driven at high voltage. In addition, the charge generation layer CGL is needed additionally, and the light emitting element may suffer from heat generation due to the high resistance of the light emitting element.

FIG. 3 illustrates an example light emitting element in the display device 100 according to aspects of the present disclosure. Hereinafter, discussions for the configuration of FIG. 3 are provided, and discussions for features equal, substantially equal, or similar to the features described with reference to FIGS. 1 and 2 may be omitted or briefly described for conciseness.

Referring to FIG. 3, in one or more example embodiments, a light emitting element may have a structure where a first stack ST1 between a first cathode electrode CE1 and an anode electrode AE and a second stack ST2 between the anode electrode AE and a second cathode electrode CE2 are disposed, and the first stack ST1 and the second stack ST2 are connected in parallel using the first cathode electrode CE1 and the second cathode electrode CE2. Herein, the light emitting element with this stack-up structure may be referred to as a parallel-type light emitting element.

For example, the first stack ST1 may have a structure in which an electron injection layer EIL, an electron transport layer ETL, an emission layer EML, a hole transport layer HTL, and a hole injection layer HIL are stacked in a direction from the first cathode electrode CE1 to the anode electrode AE, and the second stack ST2 may have a structure in which a hole injection layer HIL, a hole transport layer HTL, an emission layer EML, an electron transport layer ETL, and an electron injection layer EIL are sequentially stacked in a direction from the anode electrode AE to the second cathode electrode CE2. For example, the first stack ST1 and the second stack ST2 may be located symmetrically with respect to the anode electrode AE.

As the display device 100 includes parallel-type light emitting elements, each of which is implemented as a pair of light emitting elements with low resistance rather than one light emitting element, therefore, the display device 100 can provide advantages of being driven at low voltage and improving light emitting efficiency.

In addition, since the parallel-type light emitting element has a low resistance, heat generation can be reduced, and since an additional material is not needed, process optimization can be implemented.

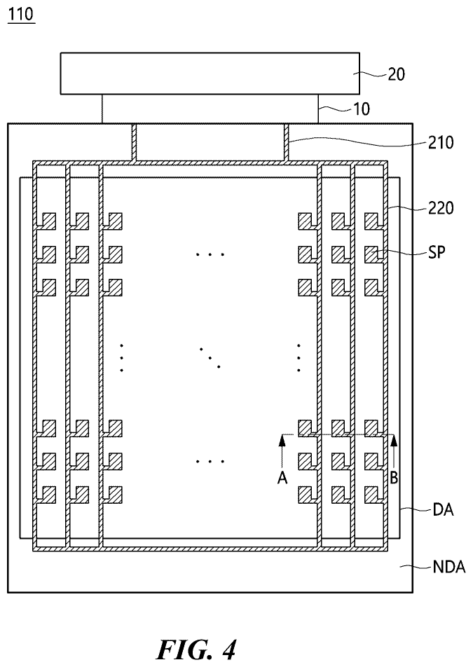

FIG. 4 is an example plan view of the display panel 110 according to aspects of the present disclosure. Hereinafter, discussions for the configuration of FIG. 4 are provided, and discussions for features equal, substantially equal, or similar to the features described with reference to FIGS. 1 to 3 may be omitted or briefly described for conciseness.

Referring to FIG. 4, in one or more example embodiments, the display panel 110 may include a substrate 111, a printed circuit board 20 configured to generate electrical signals while being located in an area outside of the substrate 111 and supply a common voltage and the like, and a flexible circuit board or connector 10 configured to connect the printed circuit board 20 and the substrate 111 to each other.

The cathode electrode may be disposed such that it extends from a display area DA to a non-display area NDA around an outer edge of the display area DA. For example, the cathode electrode may be formed integrally in the whole display area DA and a portion of the non-display area NDA outside of the display area DA.

In one or more aspects, the display panel 110 may supply a common voltage delivered through at least one common voltage supply line 210 to the cathode electrode of one or more subpixels SP through at least one auxiliary line 220, at least one connection pattern, and the like within the display area DA.

The common voltage supply line 210 and the auxiliary line 220 may be disposed in the same layer or in different layers. For example, the common voltage supply line 210 and the auxiliary line 220 may be formed by patterning a metal having a light shielding function in the same layer. In another example, the common voltage supply line 210 and the auxiliary line 220 may be disposed in different layers. In this example, the common voltage supply line 210 and the auxiliary line 220 may connected to each other by a jumping connection structure. In this implementation, the auxiliary line 220 may be formed by patterning a metal having a light shielding function.

The display area DA may include a plurality of light emitting areas spaced apart, or independently spaced apart, by a plurality of subpixels SP disposed in the display area DA. In addition, auxiliary lines 220 may be disposed to be spaced apart from each other within the display area DA. Although FIG. 4 shows an example in which the auxiliary lines 220 are disposed in a first direction (e.g., a column direction), however, aspects of the present disclosure are not limited thereto. For example, the auxiliary lines 220 may be disposed in a second direction (e.g., a row direction). In another example, the auxiliary lines 220 may include both one or more lines running in the first direction and one or more lines running in the second direction.

Referring to FIG. 4, the auxiliary line 220 may not be disposed in a second non-display area located outside of the display area DA in the second direction and a fourth non-display area located outside of the display area DA in a direction opposite to the second direction. In one or more aspects, a portion of at least one of the auxiliary lines 220 may be disposed in a first non-display area located outside of the display area DA in the first direction and a third non-display area located outside of the display area DA in a direction opposite to the first direction.

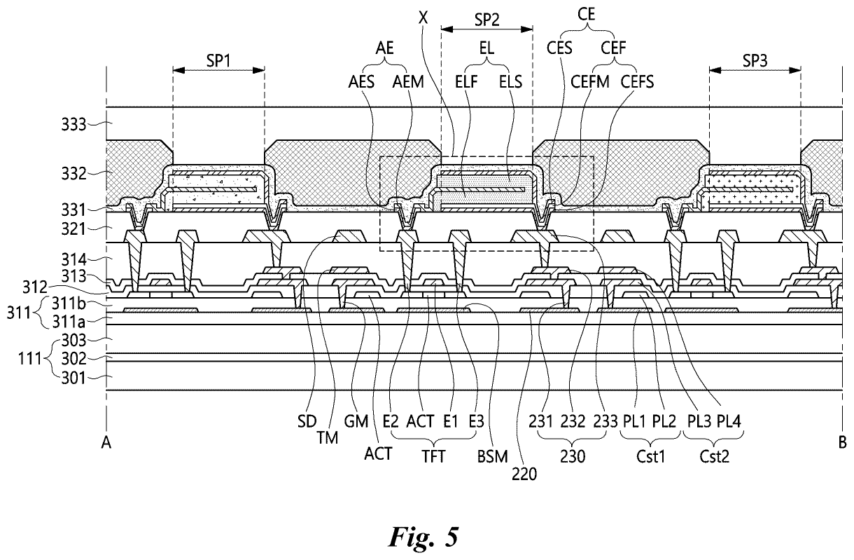

FIG. 5 is a cross-sectional view taken along line A-B of FIG. 4. Hereinafter, discussions for the configuration of FIG. 5 are provided, and discussions for features equal, substantially equal, or similar to the features described with reference to FIGS. 1 to 4 may be omitted or briefly described for conciseness.

Referring to FIG. 5, in one or more example embodiments, in terms of stack-up structure, the display panel 110 may include a transistor part, a light emitting element part, and an encapsulation part.

The substrate 111 may be in the form of a single layer or a multilayer. In an example where the substrate 111 includes a multilayer, the substrate 111 may include a first substrate 301, a substrate intermediate layer 302, and a second substrate 303. The substrate intermediate layer 302 may be located between the first substrate 301 and the second substrate 303. For example, each of the first substrate 301 and the second substrate 303 may be a polyimide (PI) layer. The substrate intermediate layer 302 may be an inorganic insulating layer. When electric charges are stored on the first substrate 301, which is a polyimide (PI) layer, the substrate intermediate layer 302 can block the charges from affecting transistors on the second substrate 303 through the second substrate 303, which is a polyimide (PI) layer.

The substrate intermediate layer 302 can block moisture from moving upwardly through the first substrate 301. For example, the substrate intermediate layer 302 may be in the form of a single layer of silicon nitride (SiNx), silicon oxide (SiOx), silicon oxynitride (SiOxNy), or aluminum oxide (AlxOy), or be in the form of a multilayer thereof, or be in the form of a double layer of silicon oxide (SiOx) and silicon nitride (SiNx). However, aspects of the present disclosure are not limited thereto.

The transistor part may include the substrate 111, several insulating layers (311, 312, 313, 314) on the substrate 111, at least one transistor TFT, at least one storage capacitor (Cst1, Cst2), and several electrodes or signal lines.

The transistor part may include the at least one transistor TFT.

The transistor TFT may include an active layer ACT, a first electrode E1, a second electrode E2, and a third electrode E3. The active layer ACT may be a semiconductor layer, but aspects of the present disclosure are not limited thereto. For example, the active layer ACT may include an oxide semiconductor, amorphous silicon, polysilicon, or low-temperature polysilicon (LTPS), but aspects of the present disclosure are not limited thereto. The transistor TFT may be a p-channel transistor or an n-channel transistor, but aspects of the present disclosure are not limited thereto.

The first electrode E1 may be a gate electrode, the second electrode E2 may be a source electrode or a drain electrode, and the third electrode E3 may be the drain electrode or the source electrode. Hereinafter, for convenience of explanation, the first electrode E1 may be the gate electrode E1, the second electrode E2 may be the source electrode E2, and the third electrode E3 may be the drain electrode E3. However, aspects of the present disclosure are not limited thereto.

For example, the active layer of the transistor TFT may include an oxide semiconductor. In another example, the active layer of the transistor TFT may include a low-temperature polysilicon. In another example, when the transistor TFT is a driving transistor DT, the active layer may include an oxide semiconductor. In another example, when the transistor TFT is a scan transistor ST, the active layer may include a low-temperature polysilicon. In another example, an active layer of a transistor TFT included in the gate driving circuit 140 implemented by a gate-in-panel (GIP) technique may include an oxide semiconductor or low-temperature polysilicon. In another example, respective active layers of all transistor TFTs disposed on the substrate 111 and transistors TFT included in the gate driving circuit 130 of the gate-in-panel (GIP) type may include an oxide semiconductor.

A buffer layer 311 may be disposed under the active layer ACT of the transistor TFT. For example, the active layer ACT of the transistor TFT may be located on the buffer layer 311.

The at least one storage capacitor (Cst1, Cst2) may include a first storage capacitor Cst1 and a second storage capacitor Cst2. The storage capacitors (Cst1, Cst2) may be disposed in several metal layers in the display panel 110. For example, the first storage capacitor Cst1 may include a first plate PL1 and a second plate PL2, and the second storage capacitor Cst may include a third plate PL3 and a fourth plate PL4.

The light emitting element part may include a plurality of light emitting elements ED disposed on at least one planarization layer 321. Each of the plurality of light emitting elements ED may include an anode electrode AE, an intermediate layer EL, and a cathode electrode CE.

The encapsulation part may include an encapsulation layer 331 on the plurality of light emitting elements ED. The encapsulation layer 331 may be in the form of a single layer or a multilayer.

Hereinafter, the stack-up structure of the display panel 110 will be described in more detail with reference to FIG. 5.

Referring to FIG. 5, the buffer layer 311 may be disposed on the substrate 111. The buffer layer 311 may be in the form of a single layer or a multilayer. When the buffer layer 311 includes a multilayer, the buffer layer 311 may include a multi-buffer layer 311a and an active buffer layer 311b.

The multi-buffer layer 311a may be in the form of a single layer of silicon nitride (SiNx), silicon oxide (SiOx), silicon oxynitride (SiOxNy), or aluminum oxide (AlxOy), or in the form of a multilayer of silicon nitride (SiNx), silicon oxide (SiOx), silicon oxynitride (SiOxNy), and/or aluminum oxide (AlxOy). However, aspects of the present disclosure are not limited thereto.

The active buffer layer 311b may be in the form of a single layer of silicon nitride (SiNx), silicon oxide (SiOx), silicon oxynitride (SiOxNy), or aluminum oxide (AlxOy), or in the form of a multilayer thereof. However, aspects of the present disclosure are not limited thereto.

The active layer ACT of the transistor TFT may be disposed on the buffer layer 311. The active layer ACT may include a channel region where a channel is formed, a source connection region on one side of the channel region, and a drain connection region on the other side of the channel region.

A gate insulating layer 312 may be disposed on the active layer ACT of the transistor TFT. The gate insulating layer 312 may be in the form of a single layer of silicon nitride (SiNx), silicon oxide (SiOx), silicon oxynitride (SiOxNy), or aluminum oxide (AlxOy), or in the form of a multilayer of silicon nitride (SiNx), silicon oxide (SiOx), silicon oxynitride (SiOxNy), and/or aluminum oxide (AlxOy). However, aspects of the present disclosure are not limited thereto.

The gate electrode E1 of the transistor TFT may be disposed on the gate insulating layer 312. The gate electrode E1 may refer to the gate electrode of the transistor, or may refer to a metal layer including the same material. Therefore, the gate electrode E1 may be included in the transistor, or may be included in one or more other circuit elements and signal lines. The gate electrode E1 may include a conductive material. For example, the gate electrode E1 may include, but is not limited to, a single layer of one, or an alloy of two or more, of molybdenum (Mo), copper (Cu), titanium (Ti), aluminum (Al), chromium (Cr), gold (Au), nickel (Ni), neodymium (Nd), and/or tungsten (W), or a multilayer of two or more, or two or more alloys of two or more, of molybdenum (Mo), copper (Cu), titanium (Ti), aluminum (Al), chromium (Cr), gold (Au), nickel (Ni), neodymium (Nd), and/or tungsten (W). However, aspects of the present disclosure are not limited thereto.

A first interlayer insulating layer 313 may be disposed on the gate electrode E1 of the transistor TFT. The first interlayer insulating layer 313 may be in the form of a single layer of silicon nitride (SiNx), silicon oxide (SiOx), silicon oxynitride (SiOxNy), or aluminum oxide (AlxOy), or a multilayer of silicon nitride (SiNx), silicon oxide (SiOx), silicon oxynitride (SiOxNy), and/or aluminum oxide (AlxOy). However, aspects of the present disclosure are not limited thereto.

A second interlayer insulating layer 314 may be disposed on the first interlayer insulating layer 313. The second interlayer insulating layer 314 may be in the form of a single layer of silicon nitride (SiNx), silicon oxide (SiOx), silicon oxynitride (SiOxNy), or aluminum oxide (AlxOy), or a multilayer of silicon nitride (SiNx), silicon oxide (SiOx), silicon oxynitride (SiOxNy), and/or aluminum oxide (AlxOy). However, aspects of the present disclosure are not limited thereto. For example, a thickness of the second interlayer insulating layer 314 may be greater than a thickness of the first interlayer insulating layer 313, but aspects of the present disclosure are not limited thereto.

The source electrode E2 and the drain electrode E3 of the transistor TFT may be disposed on the second interlayer insulating layer 323.

The source electrode E2 and the drain electrode E3 of the transistor TFT may be connected to the source connection region and the drain connection region of the active layer ACT, respectively, through holes of the second interlayer insulating layer 323, the first interlayer insulating layer 313, and the gate insulating layer 312.

The source electrode E2 and the drain electrode E3 of the transistor TFT may include a first metal and may be disposed in a first metal layer. The first metal and the first metal layer may be referred to as a first source-drain metal and a first source-drain metal layer SD. The first source-drain metal layer SD may include a conductive material. For example, the first source-drain metal layer SD may be in the form of a single layer of one, or an alloy of two or more, of molybdenum (Mo), copper (Cu), titanium (Ti), aluminum (Al), chromium (Cr), gold (Au), nickel (Ni), neodymium (Nd), and/or tungsten (W), or a multilayer of two or more, or two or more alloys of two or more, of molybdenum (Mo), copper (Cu), titanium (Ti), aluminum (Al), chromium (Cr), gold (Au), nickel (Ni), neodymium (Nd), and/or tungsten (W). However, aspects of the present disclosure are not limited thereto.

Referring to FIG. 5, the at least one storage capacitor Cst may be formed by two capacitor electrodes including, for example, a first capacitor electrode and a second capacitor electrode. In one or more aspects, the at least one storage capacitor Cst may be formed by three or more capacitor electrodes, or be in the form of two or more capacitors connected in parallel.

For example, the first storage capacitor Cst1 may be formed by the first plate PL1 and the second plate PL2. Each of the first plate PL1 and the second plate PL2 may be disposed in various metal layers disposed in the display panel 110. For example, the first plate PL1 may be a metal plate. The first plate PL1 may be located in the same metal layer as a shield metal BSM on the multi-buffer layer 311a, and include the same material as the shield metal BSM. For example, the second plate PL2 may be located in the same layer as the active layer ACT on the active buffer layer 311b, and be another active layer being in a conductivity-enabled state.

For example, the second storage capacitor Cst2 may be formed by the third plate PL3 and the fourth plate PL4. Each of the third plate PL3 and the fourth plate PL4 may be located in different metal layers disposed in the display panel 110. For example, the third plate PL3 may be a metal plate. The third plate PL3 may be located in the same metal layer GM as the gate electrode E1 on the gate insulating layer 312, and may include the same material as the gate electrode E1. The third plate PL3 may also be electrically connected to the first plate PL1 through holes of the gate insulating layer 312 and the active buffer layer 311b. For example, the fourth plate PL4 may be located in the same layer as a metal pattern TM on the first interlayer insulating layer 313, and may include the same material as the metal pattern TM.

The metal pattern TM may include, but is not limited to, a single layer of one, or an alloy of two or more, of molybdenum (Mo), copper (Cu), titanium (Ti), aluminum (Al), chromium (Cr), gold (Au), nickel (Ni), neodymium (Nd), and/or tungsten (W), or a multilayer of two or more, or two or more alloys of two or more, of molybdenum (Mo), copper (Cu), titanium (Ti), aluminum (Al), chromium (Cr), gold (Au), nickel (Ni), neodymium (Nd), and/or tungsten (W). However, aspects of the present disclosure are not limited thereto.

Referring to FIG. 5, the transistor part may further include the shield metal BSM disposed on the substrate 111, overlapped with the active layer ACT of the transistor TFT, and disposed under the active layer ACT of the transistor TFT. For example, the shield metal BSM may be disposed between the substrate 111 and the buffer layer 311, or be disposed between the multi-buffer layer 311a and the active buffer layer 311b. The shield metal BSM may include a single layer of one, or an alloy of two or more, of molybdenum (Mo), copper (Cu), titanium (Ti), aluminum (Al), chromium (Cr), gold (Au), nickel (Ni), neodymium (Nd), and/or tungsten (W), or a multiple layer of two or more, or two or more alloys of two or more, of molybdenum (Mo), copper (Cu), titanium (Ti), aluminum (Al), chromium (Cr), gold (Au), nickel (Ni), neodymium (Nd), and/or tungsten (W). However, aspects of the present disclosure are not limited thereto.

Referring to FIG. 5, the transistor part may further include at least one auxiliary line 220 to which a common voltage is applied, and at least one connection pattern 230 for electrically connecting the cathode electrode CE and the auxiliary line 220 to each other. For example, the common voltage may be a second common voltage VSS. The auxiliary line 220 may be a second common voltage line VSSL for applying the second common voltage VSS to the cathode electrode CE.

For example, the auxiliary line 220 may be located in the same metal layer as the shield metal BSM on the multi-buffer layer 311a, and include a metal of the same material as the shield metal BSM. The auxiliary line 220 may be disposed in the same metal layer as the shield metal BSM in the display area DA and include a metal of the same material as the shield metal BSM.

For example, the connection pattern 230 may include a first connection pattern 231, a second connection pattern 232, and a third connection pattern 233.

The first connection pattern 231 may electrically connect the auxiliary line 230 and the second connection pattern 232 to each other. The first connection pattern 231 may be located in the same metal layer GM as the gate electrode E1 on the gate insulating layer 312, and include a metal of the same material as the gate electrode E1. The first connection pattern 231 may be electrically connected to the auxiliary line 220 through holes of the gate insulating layer 312 and the active buffer layer 311b.

The second connection pattern 232 may electrically connect the first connection pattern 231 and the third connection pattern 233 to each other. The second connection pattern 232 may be located in the same layer as the metal pattern TM on the first interlayer insulating layer 313, and include a metal of the same material as the metal pattern TM. The second connection pattern 232 may be electrically connected to the first connection pattern 231 through a hole of the first interlayer insulating layer 313.

The third connection pattern 233 may electrically connect the second connection pattern 232 and the cathode electrode CE to each other. The third connection pattern 233 may be located in the same metal layer SD as the source and/or drain electrodes (E2, E3) on the second interlayer insulating layer 314, and include a metal of the same material as the source and/or drain electrodes (E2, E3). The third connection pattern 233 may be electrically connected to the second connection pattern 232 through a hole of the second interlayer insulating layer 314. The third connection pattern may be electrically connected to the cathode electrode CE through a hole of the planarization layer 321.

According to the foregoing configurations, as the auxiliary line 220 to which a common voltage is applied and the connection pattern 230 electrically connecting the cathode electrode CE and the auxiliary line 220 to each other are disposed within the display area DA, the display panel 110 can provide an advantage of improving or reducing an unevenness in luminance between areas in the display area DA.

Further, as the auxiliary line 220 to which a common voltage is applied and the connection pattern 230 electrically connecting the cathode electrode CE and the auxiliary line 220 to each other are disposed within the display area DA, the display panel 110 can provide an advantage of reducing a distance between subpixels SP, and producing high resolution.

Further, as the auxiliary line 220 to which a common voltage is applied and the connection pattern 230 electrically connecting the cathode electrode CE and the auxiliary line 220 to each other are disposed within the display area DA, the display panel 110 can provide an advantage of reducing a width of the bezel and thereby implementing a narrow bezel.

Referring to FIG. 5, at least one planarization layer 321 may be disposed on the transistor TFT. FIG. 5 illustrates an example where one planarization layer is disposed on the transistor TFT, but aspects of the present disclosure are not limited thereto. In one or more aspects, two or more planarization layers may be disposed on the transistor TFT.

The planarization layer 321 may be disposed on the source electrode E2 and the drain electrode E3 of the transistor TFT. For example, the planarization layer 321 may cover all or at least some of elements included in the transistor TFT.

Referring to FIG. 5, the light emitting element part may be disposed on the planarization layer 321. The light emitting element ED may be disposed on the planarization layer 321. The light emitting element ED may include the anode electrode AE, the intermediate layer EL, and the cathode electrode CE. A light emitting area of the light emitting element ED may be formed by an area where the anode electrode AE, the intermediate layer EL, and the cathode electrode CE overlap with, and contact, each other.

The cathode electrode CE may be electrically connected to the auxiliary line 220. The cathode electrode CE may be electrically connected to the auxiliary line 220 through the connection pattern 230. The cathode electrode CE may be electrically connected to the connection pattern 230 through a hole of the planarization layer 321. The connection pattern 230 may electrically connect the cathode electrode CE and the auxiliary line 220 to each other through holes of the second interlayer insulating layer 314, the first interlayer insulating layer 313, the gate insulating layer 312, and the active buffer layer 311b.

The cathode electrode CE may include a first cathode electrode CEF and a second cathode electrode CES. The intermediate layer EL may include a first intermediate layer ELF and a second intermediate layer ELS.

Referring to FIG. 5, the light emitting element ED may have a structure in which the first cathode electrode CEF, the first intermediate layer ELF, the anode electrode AE, the second intermediate layer EFS, and the second cathode electrode CES are sequentially stacked on the planarization layer 321, and the first cathode electrode CEF and the second cathode electrode CES may be electrically connected to each other.

The first cathode electrode CEF and the second cathode electrode CES may be electrically connected to the auxiliary line 220 through the connection pattern 230 disposed in a hole disposed in the planarization layer 321, and the anode electrode AE may be electrically connected to the source electrode E2 of the transistor 230 through a hole of the planarization layer 321.

The first cathode electrode CEF may be disposed on the planarization layer 321, and the first cathode electrode CEF may include a first main cathode electrode CEFM and a first sub-cathode electrode CEFS. The first sub-cathode electrode CEFS may be disposed on the planarization layer 321, and the first main cathode electrode CEFM may be disposed on the first sub-cathode electrode CEFS. The first main cathode electrode CEFM may be disposed such that both ends of the first main cathode electrode CEFM are aligned with both ends of the first sub-cathode electrode CEFS. The first sub-cathode electrode CEFS may be directly electrically connected to the connection pattern 230.

The first intermediate layer ELF may be disposed on the first cathode electrode CEF. The first intermediate layer ELF may include a hole functional layer, an emission layer, and an electron functional layer. The first intermediate layer ELF may be disposed in a structure where the electron functional layer, the emission layer, and the hole functional layer are sequentially stacked in this order on the first cathode electrode CEF.

The anode electrode AE may be disposed on the first intermediate layer ELF. The anode electrode AE may include a main anode electrode AEM and a sub-anode electrode AES. The sub-anode electrode AES may be disposed on a portion of the planarization layer 321 to overlap with the source electrode E2 of the transistor 230, and the main anode electrode AEM may be disposed on the planarization layer 321 to cover the sub-anode electrode AES. The main anode electrode AEM may be disposed along side and upper surfaces of the first intermediate layer ELF, and the sub-anode electrode AES may be disposed such that one end of the sub-anode electrode AES contacts the side surface of the first intermediate layer ELF. The sub-anode electrode AES may be directly electrically connected to the source electrode E2 of the transistor 230.

The first sub-cathode electrode CEFS and the sub-anode electrode AES may be disposed in the same layer and include the same material.

The second intermediate layer ELS may be disposed on the anode electrode AE. The second intermediate layer ELS may include a hole functional layer, an emission layer, and an electron functional layer. The second intermediate layer ELS may be disposed in a structure where the hole functional layer, the emission layer, and the electron functional layer are sequentially stacked in this order on the anode electrode AE. For example, the first intermediate layer ELF and the second intermediate layer ELS may be disposed in a symmetrical structure with respect to the anode electrode AE.

The second cathode electrode CES may be disposed on the second intermediate layer ELS. The second cathode electrode CES may be disposed such that it contacts the first cathode electrode CES in an area where the first cathode electrode CEF contacts the connection pattern 230, and be disposed along side and upper surfaces of the second intermediate layer ELS. The first cathode electrode CEF may be disposed such that one end of the first cathode electrode CEF is aligned with one end of the second cathode electrode CES.

In an example where the light emitting element ED is disposed in the top emission (TE) structure, the first cathode electrode CEF may include a reflective electrode. For example, the first sub-cathode electrode CEFS may be a transparent electrode, and the first main cathode electrode CEFM may be a reflective electrode. Each of the second cathode electrode CES and the anode electrode AE may include a transparent electrode.

In an example where the light emitting element ED is disposed in the bottom emission (BE) structure, each of the first cathode electrode CEF and the anode electrode AE may include a transparent electrode. For example, the first sub-cathode electrode CEFS and the first main cathode electrode CEFM may be transparent electrodes. The second cathode electrode CES may include a reflective electrode.

In an example where the light emitting element ED is disposed in the dual emission (DE) structure, each of the first cathode electrode CEF, the second cathode electrode CES, and the anode electrode AE may include a transparent electrode. For example, the first sub-cathode electrode CEFS and the first main cathode electrode CEFM may be transparent electrodes.

For example, the reflective electrode may include a reflective material. For example, the reflective material may be selected from, but is not limited to, aluminum (Al), molybdenum (Mo), chromium (Cr), neodymium (Nd), nickel (Ni), titanium (Ti), tantalum (Ta), copper (Cu), silver (Ag), and an aluminum alloy.

For example, the transparent electrode may include a transparent conductive oxide or a semi-transparent material.

For example, the transparent conductive oxide may be selected from, but is not limited to, indium tin oxide (ITO), indium zinc oxide (IZO), indium tin zinc oxide (ITZO), zinc oxide, and tin oxide. However, aspects of the present disclosure are not limited thereto.

For example, the semi-transparent material may be selected from magnesium (Mg), silver (Ag), aluminum (Al), molybdenum (Mo), gold (Au), calcium (Ca), titanium (Ti), copper (Cu), barium (Ba), magnesium (Mg) alloy, silver (Ag) alloy, and aluminum (Al) alloy, but aspects of the present disclosure are not limited thereto. For example, the magnesium (Mg) alloy or the silver (Ag) alloy may be a Mg: Ag alloy, and the aluminum (Al) alloy may be a LiF: Al alloy or a Li: Al alloy. In an example where the transparent electrode includes a semi-transparent material, the transparent electrode may be formed thinner than the reflective electrode.

Hereinafter, discussions are provided based on an example where the light emitting element is disposed in the top emission (TE) structure, but aspects of the present disclosure are not limited thereto.

Referring to FIG. 5, the encapsulation part is disposed on the light emitting element part and may be located on the light emitting element ED. The encapsulation part may include an encapsulation layer 200 formed to cover the light emitting element ED. The encapsulation layer 331 may be disposed such that is covers the anode electrode AE, the intermediate layer EL, and the cathode electrode CE.

The encapsulation layer 331 can prevent moisture or oxygen from penetrating into the light emitting element ED. For example, the encapsulation layer 200 can prevent moisture or oxygen from penetrating into an organic material included in the intermediate layer EL of the light emitting element ED. The encapsulation layer 200 may be in the form of a single layer or a multilayer, but aspects of the present disclosure are not limited thereto.

The encapsulation layer 331 may include an inorganic insulating material. For example, the encapsulation layer 331 may be silicon nitride (SiNx), silicon oxide (SiOx), silicon oxynitride (SiOxNy), or aluminum oxide (AlxOy). Since the encapsulation layer 331 is deposited in a low temperature atmosphere, the encapsulation layer 331 can prevent the intermediate layer EL including an organic material vulnerable to a high temperature atmosphere from being damaged during the deposition process.

Referring to FIG. 5, a bank 332 may be disposed between subpixels SP. The bank 332 may be formed between the subpixels SP such that is covers edges of light emitting elements ED on the encapsulation layer 331 to define light emitting areas.

The bank 332 may include openings corresponding to the light emitting areas. The bank 332 may include an organic film such as an acrylic resin, an epoxy resin, a phenolic resin, a polyamide resin, or a polyimide resin.

The bank 332 may be a black bank with high light absorption. In this implementation, the bank 332 can absorb light traveling in a direction where adjacent subpixels are located, and thereby, color mixing between subpixels SP can be prevented. Further, the bank 332 can absorb external light incident on the display panel 110, and thereby, reflectivity can be reduced, and reflective visibility can be improved.

For example, the black bank may be formed by dispersing a colorant in a transparent insulating resin. For example, the colorant may be selected from a carbon pigment, a metal oxide pigment, or an organic pigment. For example, the carbon pigment may be selected from carbon black, carbon nanotubes, vanta black, and the like, but aspects of the present disclosure are not limited thereto. For example, the metal oxide pigment may be titanium black (TiNxOy), a Cu-Mn-Fe-based black pigment, but aspects of the present disclosure are not limited thereto. For example, the organic pigment may be selected from lactam black, perylene black, or aniline black, but aspects of the present disclosure are not limited thereto. In another example, the colorant may be a mixture of two or more pigments or dyes having different colors.

Referring to FIG. 5, a protection layer 333 may be disposed on the bank 332 and the subpixels SP. The protection layer 333 can serve as a buffer to relieve stress between layers in a situation where the display device 100 is bent, and also serve to enhance flattening performance.

For example, the protection layer 333 may be acrylic, epoxy, phenol resin, polyamide resin, polyimide resin, polyethylene, or silicon oxycarbon (SiOCx). The protection layer 333 may include an organic insulating material. For example, the protection layer 333 may be formed by an inkjet process.

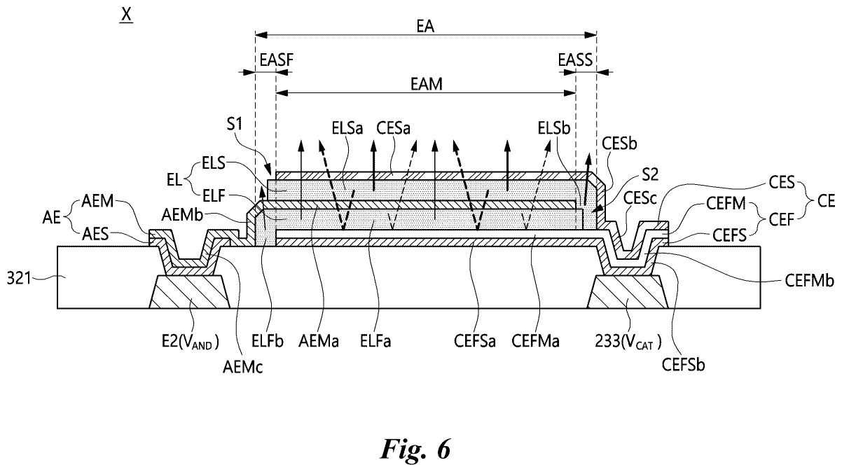

FIG. 6 is an example enlarged cross-sectional view of area X in FIG. 5, Hereinafter, discussions for the configuration of FIG. 6 are provided, and discussions for features equal, substantially equal, or similar to the features described with reference to FIGS. 1 to 5 may be omitted or briefly described for conciseness.

Referring to FIG. 6, in one or more aspects, the light emitting element ED disposed in the display panel 110 may include a light emitting area EA. The light emitting area EA may include a main light emitting area EAM, a first side light emitting area EASF, and a second side light emitting area EASS.

Referring to FIG. 6, the first cathode electrode CEF may include a first portion (CEFMa, CEFSa) disposed in an area corresponding to the upper surface of the planarization layer 321 and a second portion (CEFMb, CEFSb) corresponding to a hole of the planarization layer 321. The first portion (CEFMa, CEFSa) of the first cathode electrode CEF may be an area where the cathode electrode CE overlaps at least partially with the light emitting area in a direction perpendicular to a surface of the substrate 111, and the second portion (CEFMb, CEFSb) of the first cathode electrode CEF may be an area where the cathode electrode CE overlaps at least partially with the third connection pattern 233 in the direction perpendicular to the surface of the substrate 111. For example, the first sub-cathode electrode CEFS may include the first portion CEFSa and the second portion CEFSb, and the first main cathode electrode CEFM may include the first portion CEFMa and the second portion CEFMb.

Referring to FIG. 6, the first intermediate layer ELF may include a first portion ELFa and a second portion ELFb. The first portion ELFa of the first intermediate layer ELF may be an area where the first intermediate layer ELF overlaps with the first portion (CEFMa, CEFSa) of the first cathode electrode CEF in the direction perpendicular to the surface of the substrate 111, and the second portion ELFb of the first intermediate layer ELF may be an area where the first intermediate layer ELF does not overlap with the first portion (CEFMa, CEFSa) of the first cathode electrode CEF in the direction perpendicular to the surface of the substrate 111.

Referring to FIG. 6, the anode electrode AE may include a first portion AEMa, a second portion AEMb, and a third portion AEMc. The first portion AEMa, the second portion AEMb, and the third portion AEMc of the anode electrode AE may represent the first portion AEMa, the second portion AEMb, and the third portion AEMc of the main anode electrode AEM. The first portion AEMa of the anode electrode AE may be an area where the anode electrode AE overlaps with the first portion (CEFMa, CEFSa) of the first cathode electrode CEF in the direction perpendicular to the surface of the substrate 111, the third portion AEMc of the anode electrode AE may be an area where the main anode electrode AEM and the sub-anode electrode AES overlap with each other, and the second portion AEMb of the anode electrode AE may be an area between the first portion AEMa and the third portion AMEc of the anode electrode AE. In this implementation, one end of the first portion ELFa of the first intermediate layer ELF may protrude more than one end of the first portion AEMa of the anode electrode AE in a second side S2.

Referring to FIG. 6, the second intermediate layer ELS may include a first portion ELSa and a second portion ELSb. The first portion ELSa of the second intermediate layer ELS may be an area where the second intermediate layer ELS overlaps with the first portion AEMa of the anode electrode AE in the direction perpendicular to the surface of the substrate 111, and the second portion ELSb of the second intermediate layer ELS may be an area where the second intermediate layer ELS does not overlap with the first portion AEMa of the anode electrode AE in the direction perpendicular to the surface of the substrate 111.

Referring to FIG. 6, the second cathode electrode CES may include a first portion CESa, a second portion CESb, and a third portion CESc. The first portion CESa of the second cathode electrode CES may be an area where the second cathode electrode CES overlaps with the first portion (CEFMa, CEFSa) of the first cathode electrode CEF in the direction perpendicular to the surface of the substrate 111, the third portion CESc of the second cathode electrode CES may be an area where the second cathode electrode CES overlaps with the second portion (CEFMb, CEFSb) of the first cathode electrode CEF in the direction perpendicular to the surface of the substrate 1111, and the second portion CESb of the second cathode electrode CES may be an area between the first portion CESa and the third portion CESc of the second cathode electrode CES. In this implementation, one end of the first portion ELSa of the second intermediate layer ELS may protrude more than one end of the first portion CESa of the second cathode electrode CES in a first side S1.

Referring to FIG. 6, the main light emitting area EAM may correspond to an area where the first cathode electrode CEF, the first intermediate layer ELF, the anode electrode AE, the second intermediate layer ELS, and the second cathode electrode CES overlap with, and contact, each other in the direction perpendicular to the surface of the substrate 1111.

For example, the first portion (CEFMa, CEFSa) of the first cathode electrode CEF, the first portion ELFa of the first intermediate layer ELF, and the first portion AEMa of the anode electrode AE may overlap with, and contact, each other in the direction perpendicular to the surface of the substrate 1111. In this implementation, some (solid line) of light emitted from the first intermediate layer ELF may pass through the anode electrode AE and exit the display panel 110, and some (dotted line) of the light may be reflected from the first main cathode electrode CEFM and then pass through the anode electrode AE and exit the display panel 110.

For example, the first portion AEMa of the anode electrode AE, the first portion ELSa of the second intermediate layer ELS, and the first portion CESa of the second cathode electrode CES may overlap with, and contact, each other in the direction perpendicular to the surface of the substrate 1111. In this implementation, some (solid line) of light emitted from the second intermediate layer ELS may pass through the second cathode electrode CES and exit the display panel 110, and some (dotted line) of the light may pass through the anode electrode AE, be reflected by the first main cathode electrode CEFM, then pass through the anode electrode AE again, and exit the display panel 110.

Referring to FIG. 6, the first side light emitting area EASF may correspond to an area where one end of the first cathode electrode CEF, a side surface of the first intermediate layer ELF, and a side surface of the anode electrode AE overlap with, and contact, each other in a direction parallel to the surface of the substrate 111.

For example, one end of the first portion (CEFMa, CEFSa) of the first cathode electrode CEF, the second portion ELFb of the first intermediate layer ELF, and the second portion AEMb of the anode electrode AE may overlap with, and contact, each other in the direction parallel to the surface of the substrate 111. In this implementation, light (solid line) emitted from the first intermediate layer ELF may pass through the anode electrode AE and exit the display panel 110.

Referring to FIG. 6, the second side light emitting area EASS may correspond to an area where one end of the anode electrode AE, a side surface of the second intermediate layer ELS, and a side surface of the second cathode electrode CES overlap with, and contact, each other in the direction parallel to the surface of the substrate 111.

For example, one end of the first portion AEMa of the anode electrode AE, the second portion ELSb of the second intermediate layer ELS, and the second portion CESb of the second cathode electrode CES may overlap with, and contact, each other in the direction parallel to the surface of the substrate 111. In this implementation, light (solid line) emitted from the second intermediate layer ELS may pass through the second cathode electrode CES and exit the display panel 110.

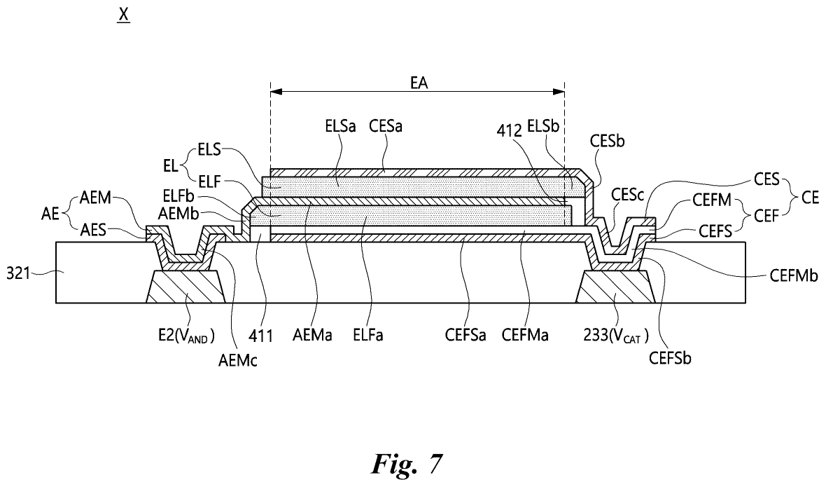

FIG. 7 is an example enlarged cross-sectional view of area X in FIG. 5. Hereinafter, discussions for the configuration of FIG. 7 are provided, and discussions for features equal, substantially equal, or similar to the features described with reference to FIGS. 1 to 6 may be omitted or briefly described for conciseness.

Referring to FIG. 7, considering that the configuration of FIG. 7 is equal, or substantially equal, to the configuration of FIG. 6 except that insulating patterns (411, 412) are disposed in respective portions of the second portion ELFb of the first intermediate layer ELF and the second portion ELSb of the second intermediate layer ELS of FIG. 6, discussions for features equal, substantially equal, or similar to the features of FIG. 6 are omitted for conciseness.

Referring to FIG. 7, in an area where one end of the first portion (CEFMa, CEFSa) of the first cathode electrode CEF and the second portion AEMb of the anode electrode AE overlap with each other in the direction parallel to the surface of the substrate 111, the second portion ELFb of the first intermediate layer ELF may not be disposed, and instead, the insulating pattern 411 may be disposed. As the insulating pattern 411 is disposed in the second portion ELFb of the first intermediate layer ELF, light emitted from the first side emission region EASF can be prevented from leaking into an adjacent subpixel and causing color mixing.

Referring to FIG. 7, in an area where one end of the first portion AEMa of the anode electrode AE and the second portion CESb of the second cathode electrode CES overlap with each other in the direction parallel to the surface of the substrate 111, the second portion ELSb of the second intermediate layer ELS may not be disposed, and instead, the insulating pattern 412 may be disposed. As the insulating pattern 412 is disposed in the second portion ELSb of the second intermediate layer ELS, light emitted from the second side emission region EASS can be prevented from leaking into an adjacent subpixel and causing color mixing.

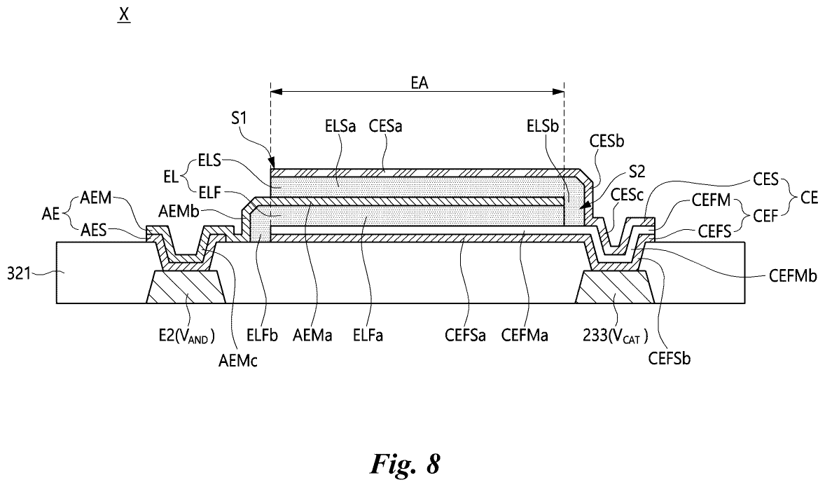

FIG. 8 is an example enlarged cross-sectional view of area X in FIG. 5. Hereinafter, discussions for the configuration of FIG. 8 are provided, and discussions for features equal, substantially equal, or similar to the features described with reference to FIGS. 1 to 7 may be omitted or briefly described for conciseness.

Referring to FIG. 8, considering that the configuration of FIG. 8 is equal, or substantially equal, to the configuration of FIG. 6 except that respective portions of the intermediate layer EL in the first side S1 and the second side S2 in the configuration of FIG. 6 are removed, discussions for features equal, substantially equal, or similar to the features of FIG. 6 are omitted for conciseness.

Referring to FIG. 8, one end of the first portion ELSa of the second intermediate layer ELS in the first side S1 and one end of the first portion CESa of the second cathode electrode CES may be aligned with each other. Further, one end of the first portion ELFa of the first intermediate layer ELF in the second side S2 and one end of the first portion AEMa of the anode electrode AE may be aligned with each other.

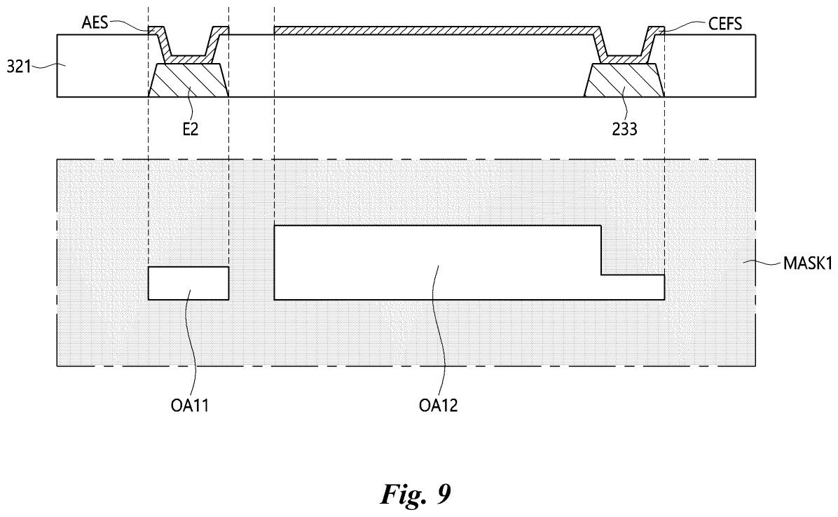

FIGS. 9 to 14 illustrate an example process for manufacturing a light emitting element according to aspects of the present disclosure. Hereinafter, discussions for the configurations of FIGS. 9 to 14 are provided, and discussions for features equal, substantially equal, or similar to the features described with reference to FIGS. 1 to 8 may be omitted or briefly described for conciseness.

The process illustrated in FIGS. 9 to 14 is a part of processes for manufacturing the display device 100, and corresponds to a process for forming a light emitting element ED on a planarization layer 321.

Referring to FIG. 9, a first sub-cathode electrode CEFS and a sub-anode electrode AES may be formed on the planarization layer 321.

The first sub-cathode electrode CEFS and the sub-anode electrode AES may be formed using a first mask MASK1 with a first-first hole OA11 corresponding to a source electrode E2 of a transistor 230 and a first-second hole OA12 corresponding to a third connection pattern 233.

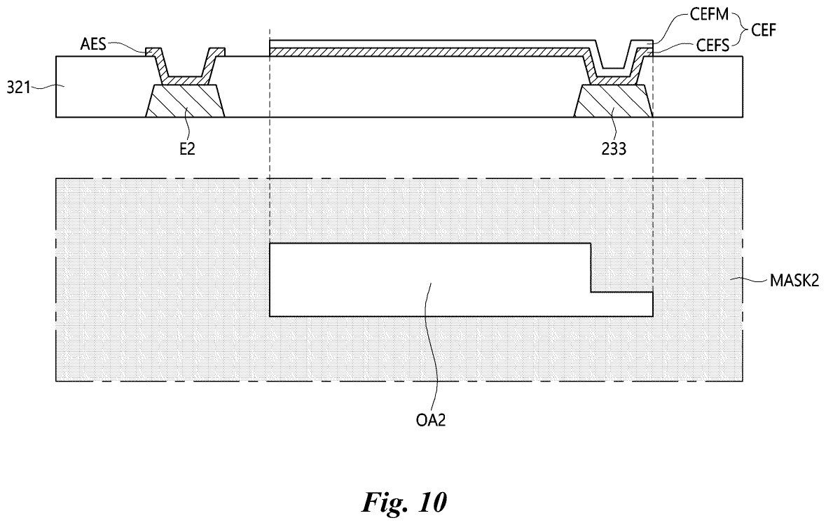

Next, referring to FIG. 10, a first main cathode electrode CEFM may be formed on the first sub-cathode electrode CEFS, thereby resulting in a first cathode electrode CEF being formed.

The first main cathode electrode CEFM may be formed using a second mask MASK2 with a second hole OA2 corresponding to the first sub-cathode electrode CEFS.

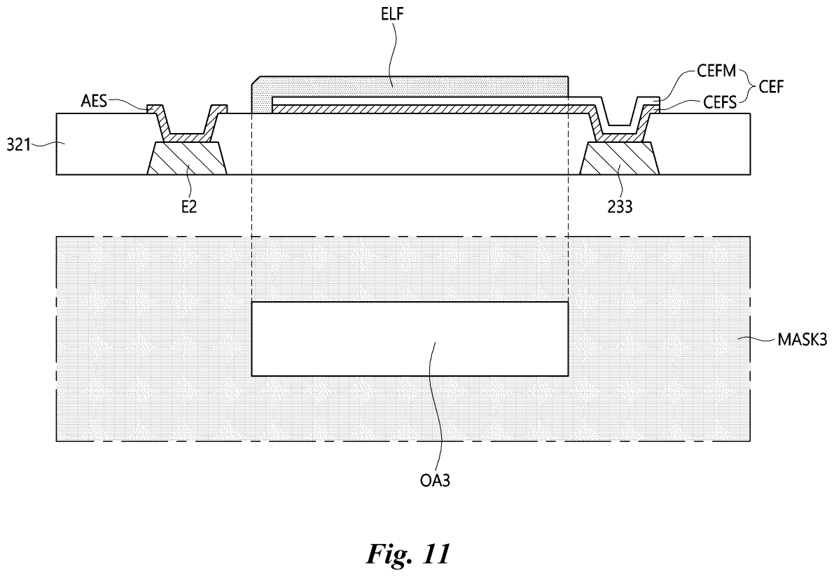

Next, referring to FIG. 11, a first intermediate layer ELF may be formed on the first cathode electrode CEF.

The first intermediate layer ELF may be formed using a third mask MASK3 with a third hole OA3 to overlap with at least a portion of the first cathode electrode CEF.

The first intermediate layer ELF may be deposited such that an electron functional layer, an emission layer, and a hole functional layer are sequentially deposited in this order. For example, an electron injection layer EIL, an electron transport layer ETL, an emission layer EML, a hole transport layer HTL, and a hole injection layer HIL may be sequentially deposited in this order.

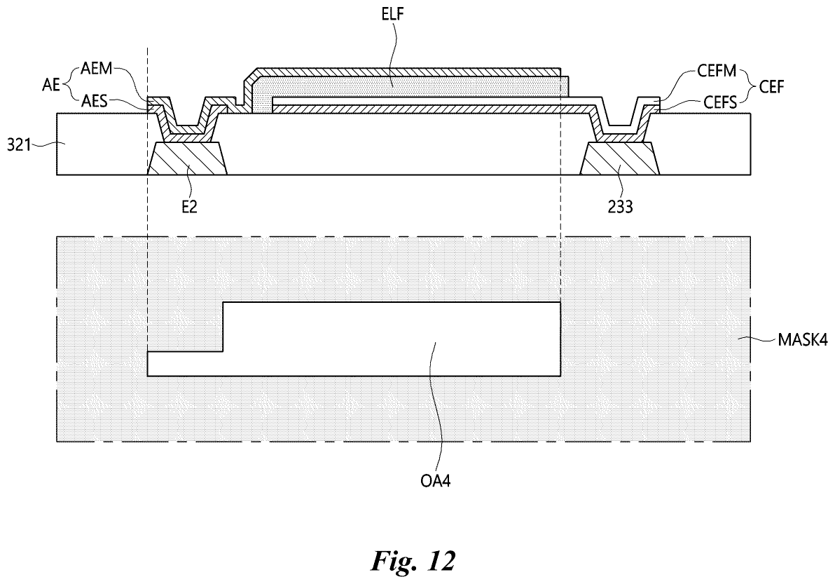

Next, referring to FIG. 12, a main anode electrode AEM may be formed on the first intermediate layer ELF, thereby resulting in an anode electrode AE being formed.

The main anode electrode AEM may be formed using the fourth mask MASK4 with a fourth hole OA4 to overlap with at least a portion of the first intermediate layer ELF and the sub-anode electrode AES.

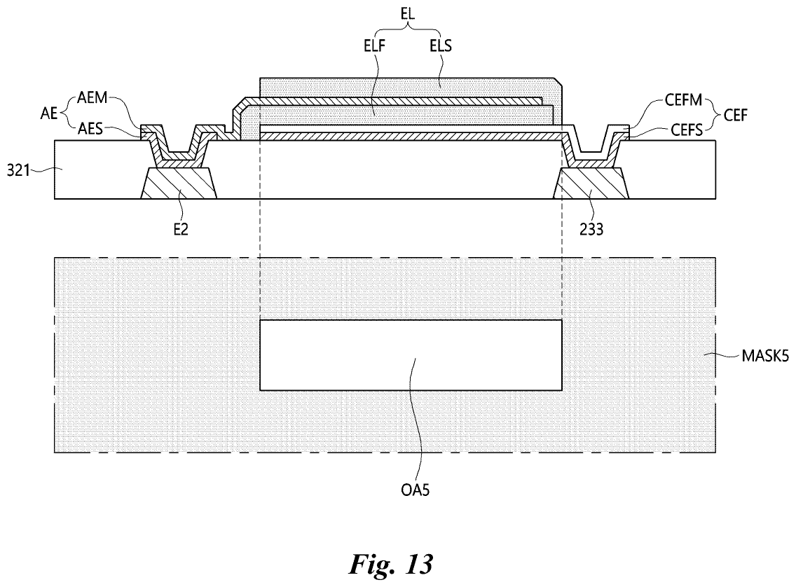

Next, referring to FIG. 13, a second intermediate layer ELS may be formed on the anode electrode AE, thereby resulting in an intermediate layer EL being formed.

The second intermediate layer ELS may be formed using a fifth mask MASK3 with a fifth hole OA5 to overlap with at least a portion of the anode electrode AE.

The second intermediate layer ELS may be formed symmetrically with the first intermediate layer ELF with respect to the anode electrode AE. The second intermediate layer ELS may be deposited such that a hole functional layer, an emission layer, and an electron functional layer are sequentially deposited in this order. For example, a hole injection layer HIL, a hole transport layer HTL, an emission layer EML, an electron transport layer ETL, and an electron injection layer EIL may sequentially deposited in this order.

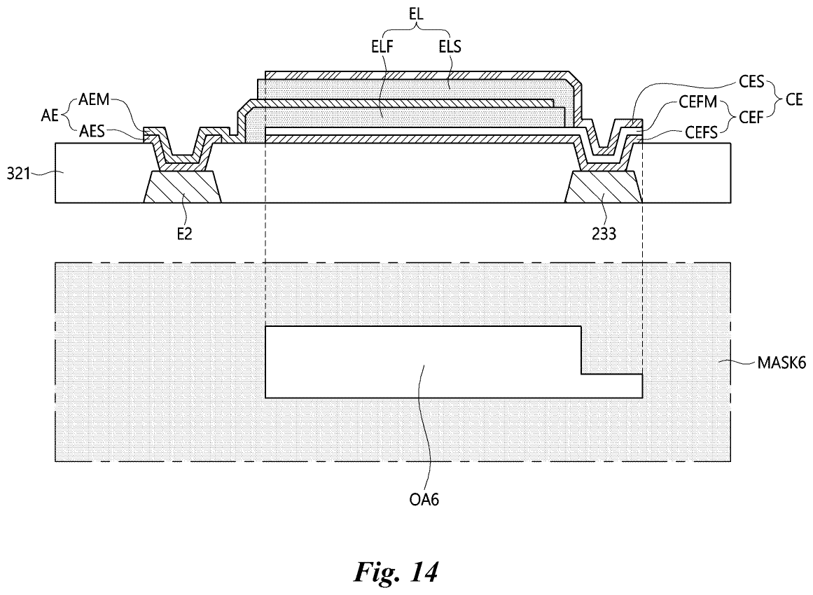

Next, referring to FIG. 14, a second cathode electrode CES may be formed on the second intermediate layer ELS, thereby resulting in a cathode electrode CE being formed.

The second cathode electrode CES may be formed using a sixth mask MASK6 with a sixth hole OA6 corresponding to the first cathode electrode CEF. In this implementation, the sixth mask MASK6 may be the same mask as the second mask MASK2.

The examples, aspects, and embodiments for the display device 100 described herein may be described as follows.

According to the one or more example embodiments described herein, a display device can be provided that includes a substrate including a display area, at least one light emitting element disposed in the display area, and an auxiliary line disposed in the display area. In one or more aspects, the light emitting element may include a first cathode electrode on the substrate, a first intermediate layer on the first cathode electrode, an anode electrode on the first intermediate layer, a second intermediate layer on the anode electrode, and a second cathode electrode on the second intermediate layer. In one or more aspects, the auxiliary line may be electrically connected to the first cathode electrode and the second cathode electrode in the display area.

In one or more aspects, the first intermediate layer and the second intermediate layer may be connected in parallel.

In one or more aspects, the first intermediate layer and the second intermediate layer may be disposed symmetrically with respect to the anode electrode.

In one or more aspects, the first intermediate layer may include a first electron functional layer on the first cathode electrode, a first emission layer on the first electron functional layer, and a first hole functional layer on the first emission layer. In one or more aspects, the second intermediate layer may include a second hole functional layer on the anode electrode, a second emission layer on the second hole functional layer, and a second electron functional layer on the second emission layer.

In one or more aspects, the first cathode electrode may include a reflective electrode, the anode electrode may include a first transparent electrode, and the second cathode electrode may include a second transparent electrode.

In one or more aspects, the first cathode electrode may include a first main cathode electrode and a first sub-cathode electrode. In one or more aspects, the first main cathode electrode may include a reflective electrode, and the first sub-cathode electrode may include a third transparent electrode.

In one or more aspects, the anode electrode may include a main anode electrode and a sub-anode electrode. In one or more aspects, the main anode electrode may include a first transparent electrode, and the sub-anode electrode may include a third transparent electrode.

In one or more aspects, the first sub-cathode electrode and the sub-anode electrode may be spaced apart from each other, be disposed in the same layer, and include the same material.

In one or more aspects, the display area may include a light emitting area corresponding to an area where the first cathode electrode, the first intermediate layer, the anode electrode, the second intermediate layer, and the second cathode electrode overlap with each other.

In one or more aspects, the light emitting area may include a main light emitting area corresponding to an area where the first cathode electrode, the first intermediate layer, the anode electrode, the second intermediate layer, and the second cathode electrode overlap with each other in a direction perpendicular to a surface of the substrate.

In one or more aspects, the light emitting area may include a first side light emitting area corresponding to an area where the first cathode electrode, the first intermediate layer, and the anode electrode overlap with each other in a direction parallel to the surface of the substrate, and a second light emitting area corresponding to an area where the anode electrode, the second intermediate layer, and the second cathode electrode overlap with each other in the direction parallel to the surface of the substrate.

In one or more aspects, in a direction parallel to a surface of the substrate, one end of the first intermediate layer may protrude further than one end of the anode electrode, and one end of the second intermediate layer may protrude further than one end of the second cathode electrode.

In one or more aspects, in a direction parallel to a surface of the substrate, one end of the first intermediate layer may be aligned with one end of the anode electrode, and one end of the second intermediate layer may be aligned with one end of the second cathode electrode.

In one or more aspects, in a direction parallel to a surface of the substrate, a first insulating pattern may be disposed between one end of the first cathode electrode and the anode electrode, and a second insulating pattern may be disposed between the anode electrode and the second cathode electrode.

In one or more aspects, the display device may further include a connection pattern electrically connecting the first cathode electrode and the second cathode electrode to the auxiliary line.

In one or more aspects, the connection pattern may include a first connection pattern, a second connection pattern, and a third connection pattern. In one or more aspects, the first connection pattern may be electrically connected to the auxiliary line, and the third connection pattern may be electrically connected to the first cathode electrode and the second cathode electrode.

In one or more aspects, the display device may further include a transistor including a gate electrode, a source electrode, and a drain electrode. In one or more aspects, the first connection pattern may be disposed in the same layer as the gate electrode, and the third connection pattern may be disposed in the same layer as the source electrode and the drain electrode.

In one or more aspects, the display device may further include a metal pattern disposed on the gate electrode, and the second connection pattern may be disposed in the same layer as the metal pattern.

In one or more aspects, the display device may further include a shield metal disposed under the transistor, and the auxiliary line may be disposed in the same layer, and include the same material, as the shield metal.

In one or more aspects, the display device may further include an encapsulating layer disposed to cover the light emitting element and comprising an inorganic insulating material.

In one or more aspects, the display area may include a plurality of subpixels each comprising the corresponding light emitting element. In one or more aspects, a bank may be disposed on the encapsulation layer and define the plurality of subpixels.

In one or more aspects, the bank may be a black bank.

In one or more aspects, the display device may further include a common voltage supply line electrically connected to the auxiliary line and supplying a common voltage.

According to the one or more aspects described herein, a display device may be provided that is capable of being driven at low voltage and improving light emitting efficiency by including a structure where parallel-type light emitting elements are disposed.

According to the one or more aspects described herein, a display device may be provided that is capable of reducing heat generation of light emitting elements by including a structure where parallel-type light emitting elements are disposed.

According to the one or more aspects described herein, a display device may be provided that is capable of improving an unevenness in luminance between areas in a display area by including a structure where a cathode electrode, an auxiliary line, and a connection pattern are disposed in a display area.

According to the one or more aspects described herein, a display device may be provided that is capable of reducing a distance between subpixels (e.g., a width of a non-light emitting area) and thereby achieving high resolution by including a structure where a cathode electrode, an auxiliary line, and a connection pattern are disposed in a display area.

According to the one or more aspects described herein, a display device may be provided that is capable of reducing a width of a bezel area and thereby realizing a narrow bezel by including a structure where a cathode electrode, an auxiliary line, and a connection pattern are disposed in a display area.

According to the one or more aspects described herein, a display device may be provided that is capable of enabling process optimization without changing materials by including a structure where parallel-type light emitting elements are disposed.

According to the one or more aspects described herein, a display device may be provided that is capable of reducing a distance between subpixels, and achieving high resolution and low power driving.

In one embodiment, a display device is provided comprising a substrate including a display area, an auxiliary line disposed within the display area, and a plurality of subpixels arranged in the display area. Each subpixel includes a light emitting element configured with a dual-emission stack structure, wherein the light emitting element comprises a first emission stack, a second emission stack, and an anode electrode disposed between the first and second emission stacks. The first emission stack includes a first cathode electrode, a first electron transport layer, a first emission layer, and a first hole transport layer, sequentially stacked in a first direction toward the anode electrode. The second emission stack includes a second hole transport layer, a second emission layer, a second electron transport layer, and a second cathode electrode, sequentially stacked in a second direction opposite to the first direction from the anode electrode. The first and second cathode electrodes are electrically connected to the auxiliary line, forming a parallel connection within the display area.

In some embodiments, the first and second emission stacks are disposed in a mirror-symmetric arrangement with respect to a plane defined by the anode electrode. This symmetric stack configuration allows both stacks to contribute to light emission simultaneously, thereby reducing overall electrical resistance and enhancing luminous efficiency. The anode electrode functions as a shared electrode for both stacks, enabling balanced charge injection and stable driving characteristics across the light emitting element. The described architecture is compatible with various emission schemes, including top emission, bottom emission, or dual emission modes, depending on the optical transparency or reflectivity of the anode and cathode electrode materials.

In further embodiments, the first and second cathode electrodes are formed in distinct vertical planes relative to the substrate and are electrically coupled via a vertical conductive structure. The vertical conductive structure may include one or more connection patterns disposed across multiple interconnect layers within the panel stack. In one example, a first connection pattern is disposed in the same metal layer as a gate electrode of a thin-film transistor, while a second connection pattern is formed in a higher metal layer containing a metal routing pattern. These connection patterns establish electrical continuity between the vertically spaced cathode electrodes and the auxiliary line without extending outside the display area.

By locating the auxiliary line and all associated connection patterns entirely within the display area, the display device can achieve reduced bezel width, improved pixel integration, and simplified routing of common voltages. The parallel configuration of the cathode electrodes facilitates uniform current distribution and reduces the operating voltage required to drive the light emitting elements. This results in enhanced power efficiency and improved thermal performance, making the disclosed architecture particularly suitable for high-resolution, low-power display applications.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. These and other changes can be made to the embodiments in light of the above-detailed

description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area;
a light emitting element disposed in the display area; and
an auxiliary line disposed in the display area,
wherein the light emitting element includes:
a first cathode electrode on the substrate;
a first intermediate layer on the first cathode electrode;
an anode electrode on the first intermediate layer;
a second intermediate layer on the anode electrode; and
a second cathode electrode on the second intermediate layer, and
wherein the auxiliary line is electrically connected to the first cathode electrode and the second cathode electrode.

2. The display device of claim 1, wherein the first intermediate layer and the second intermediate layer are connected in parallel.

3. The display device of claim 1, wherein the first intermediate layer and the second intermediate layer are disposed symmetrically with respect to the anode electrode.

4. The display device of claim 3, wherein the first intermediate layer comprises:
a first electron functional layer on the first cathode electrode;
a first emission layer on the first electron functional layer; and
a first hole functional layer on the first emission layer, and
wherein the second intermediate layer comprises:
a second hole functional layer on the anode electrode;
a second emission layer on the second hole functional layer; and
a second electron functional layer on the second emission layer.

5. The display device of claim 1, wherein the first cathode electrode comprises a reflective electrode, and each of the anode electrode and the second cathode electrode comprises a transparent electrode.

6. The display device of claim 5, wherein the first cathode electrode comprises a first main cathode electrode and a first sub-cathode electrode, and
wherein the first main cathode electrode comprises the reflective electrode, and the first sub-cathode electrode comprises a transparent electrode.

7. The display device of claim 6, wherein the anode electrode comprises a main anode electrode and a sub-anode electrode, and
wherein the first sub-cathode electrode and the sub-anode electrode are spaced apart from each other, are disposed in the same layer, and comprise the same material.

8. The display device of claim 1, wherein the display area comprises a light emitting area corresponding to an area where the first cathode electrode, the first intermediate layer, the anode electrode, the second intermediate layer, and the second cathode electrode overlap with each other, and
wherein the light emitting area comprises a main light emitting area corresponding to an area where the first cathode electrode, the first intermediate layer, the anode electrode, the second intermediate layer, and the second cathode electrode overlap with each other in a direction perpendicular to a surface of the substrate.

9. The display device of claim 8, wherein the light emitting area comprises:
a first side light emitting area corresponding to an area where the first cathode electrode, the first intermediate layer, and the anode electrode overlap with each other in a direction parallel to the surface of the substrate; and
a second side light emitting area corresponding to an area where the anode electrode, the second intermediate layer, and the second cathode electrode overlap with each other in the direction parallel to the surface of the substrate.

10. The display device of claim 1, wherein in a direction parallel to a surface of the substrate, one end of the first intermediate layer protrudes further than one end of the anode electrode, and one end of the second intermediate layer protrudes further than one end of the second cathode electrode.

11. The display device of claim 1, wherein, in a direction parallel to a surface of the substrate, one end of the first intermediate layer is aligned with one end of the anode electrode, and one end of the second intermediate layer is aligned with one end of the second cathode electrode.

12. The display device of claim 1, wherein, in a direction parallel to a surface of the substrate, a first insulating pattern is disposed between one end of the first cathode electrode and the anode electrode, and a second insulating pattern is disposed between the anode electrode and the second cathode electrode.

13. The display device of claim 1, further comprising a connection pattern electrically connecting the first cathode electrode and the second cathode electrode to the auxiliary line.

14. The display device of claim 13, further comprising:
a transistor comprising a gate electrode, a source electrode, and a drain electrode,
wherein the connection pattern comprises a first connection pattern, a second connection pattern, and a third connection pattern, and
wherein the first connection pattern is disposed in the same layer as the gate electrode, and the third connection pattern is disposed in the same layer as the source electrode and the drain electrode.

15. The display device of claim 14, further comprising a metal pattern disposed on the gate electrode,
wherein the second connection pattern is disposed in the same layer as the metal pattern.

16. The display device of claim 14, further comprising a shield metal disposed under the transistor,
wherein the auxiliary line is disposed in the same layer as the shield metal.

17. The display device of claim 1, further comprising an encapsulating layer disposed to cover the light emitting element and comprising an inorganic insulating material.

18. The display device of claim 17, wherein the display area comprises a plurality of subpixels each comprising the light emitting element, and
wherein a bank is disposed on the encapsulation layer and defines the plurality of subpixels.

19. The display device of claim 18, wherein the bank is a black bank.

20. The display device of claim 1, further comprising a common voltage supply line electrically connected to the auxiliary line and supplying a common voltage.

21. A display device comprising:
a substrate including a display area;
an auxiliary line in the display area; and
a plurality of subpixels disposed in the display area, each subpixel including a light emitting element having:
a first emission stack;
a second emission stack; and
an anode electrode between the first emission stack and the second emission stack,
wherein the first emission stack includes:
a first cathode electrode, a first electron transport layer, a first emission layer, and a first hole transport layer, sequentially stacked in a first direction toward the anode electrode,
wherein the second emission stack includes:
a second hole transport layer, a second emission layer, a second electron transport layer, and a second cathode electrode, sequentially stacked in a second direction opposite to the first direction from the anode electrode,
wherein the first cathode electrode and the second cathode electrode are electrically connected to the auxiliary line.

22. The display device of claim 21, wherein the first and second emission stacks are mirror-symmetric about a plane defined by the anode electrode.

23. The display device of claim 21, wherein the first and second cathode electrodes are formed in distinct vertical planes relative to the substrate and connected via a vertical conductive structure.

24. The display device of claim 23, wherein the vertical conductive structure includes one or more connection patterns disposed across different layers.

25. The display device of claim 24, further comprising a transistor including a gate electrode, a source electrode, and a drain electrode, wherein the one or more connection patterns include a first connection pattern disposed in the same layer as the gate electrode.

26. The display device of claim 25, wherein the one or more connection patterns include a second connection pattern disposed in a layer containing a metal pattern above the gate electrode, and
wherein the one or more connection patterns are disposed entirely within the display area.

27. The display device of claim 21, wherein the auxiliary line is disposed entirely within the display area.

28. The display device of claim 21, wherein, in operation, the anode electrode is commonly shared by the first and second emission stacks.

29. The display device of claim 21, wherein the first and second cathode electrodes are connected in parallel to the auxiliary line.

30. The display device of claim 29, wherein, during operation, the display device is configured to operate at a reduced voltage based on the parallel connection of the first and second cathode electrodes.
